(19) United States
(12) Patent Application Publication
(10) Pub. No.: US 2026/0249485 A1
(43) Pub. Date: Aug. 27, 2026

(54) MOUNTING TOOL AND MOUNTING APPARATUS

(71) Applicant: SHIBAURA MECHATRONICS CORPORATION, Yokohama-shi (JP)

(72) Inventors: Keigou HIROSE, Yokohama-shi (JP); Nobuaki KONISHI, Yokohama-shi (JP)

(73) Assignee: SHIBAURA MECHATRONICS CORPORATION, Yokohama-shi (JP)

(21) Appl. No.: 19/535,028

(22) Filed: Feb. 10, 2026

(30) Foreign Application Priority Data
Feb. 27, 2025 (JP) 2025-030378
Nov. 13, 2025 (JP) 2025-194012

(51) Int. Cl. B25J 15/06; H10P 72/78

(52) U.S. Cl. CPC B25J 15/0616; H10P 72/78

(57) ABSTRACT

A mounting tool includes a holding body configured to hold an electronic component to be heated, and a support body configured to support the holding body, wherein the holding body includes a holder configured to hold the electronic component on a holding surface as a lower surface of the holder, and a placer provided above the holding surface and having a placement surface facing downward, and wherein the support body includes an accommodator configured to accommodate the placer so that the holding surface is exposed downward and the holding body is movable vertically, and a support configured to support the holding body by being in contact with the placement surface.

### CROSS-REFERENCE TO RELATED APPLICATIONS

This application is based upon and claims the benefit of priority from Japanese Patent Application No. 2025-030378, filed on February 27, 2025, and Japanese Patent Application No. 2025-194012, filed on November 13, 2025, the entire contents of which are incorporated herein by reference.

### TECHNICAL FIELD

The present disclosure relates to a mounting tool and a mounting apparatus.

### BACKGROUND

Flip-chip mounting, for example, is used to mount electronic components on a substrate. The flip-chip mounting is a method of mounting an electronic component such as a semiconductor chip with its electrode-formed surface facing a substrate having a conductive pattern formed thereon.

In the flip-chip mounting, for example, a mounting tool at a lower end of a mounting head holds the electronic component so that the surface thereof having solder bumps faces the substrate. For example, when the mounting head is positioned above the substrate, the substrate is arranged so that the surface having the conductive pattern faces upward, and the electronic component is held by the mounting tool so that the surface having the bumps faces downward. Further, the mounting head is lowered to bring the bumps of the electronic component held by the mounting tool into contact with solder-made protruding electrodes (bumps) formed on the conductive pattern of the substrate, and heats the bumps of the electronic component while applying a load. Thus, the bumps on both sides are melted and then hardened to establish an electrical connection.

When the bumps are shifted or crushed during the melting due to the load applied by the mounting head to the bumps, the electrode or the conductive pattern may be short-circuited. In order to prevent the problem described above, the mounting head may apply a light load to the bumps during the melting, so that the melted bumps are not crushed. However, the mounting head needs to be equipped with a pipe for vacuum suction of the electronic component by the mounting tool, a heater and a wiring for heating the bumps, and other components. Thus, the load applied from the mounting head to the electronic component via the mounting tool may be significantly greater than the load required to prevent the bumps from being crushed, and may be difficult to control. Further, when the mounting tool thermally expands due to the heating and presses the electronic component downward, it becomes even more difficult to control the load applied to the bumps, and the bumps may be short-circuited easily due to the crush of the bumps.

In order to address this issue, in the related art, the mounting tool is raised at a moment of melting of the bumps to prevent the bumps from being crushed. However, the above-described operation of the mounting tool requires detecting the moment of the melting, thereby complicating the process. Further, even when attempting to raise the mounting head at the moment of melting of the bumps, a time lag is generated between detecting the melting and driving the mounting head. Therefore, the bumps are affected by the load applied to the electronic component and the thermal expansion of the mounting tool at a moment immediately after the melting of the bumps. In recent years, miniaturization in size of bumps on an electronic component and a substrate is progressing. Therefore, even a slight load may cause crushing of the bumps. In other words, the method of raising the mounting tool at the moment of the melting of the bumps has limited effectiveness in preventing the bumps from being crushed. Accordingly, the load applied to the bumps may be reduced before the melting of the bumps. Considering factors such as the thermal expansion of the mounting tool and the like, it is extremely complex and difficult to control a stop position of the mounting tool to reduce the load of the mounting head before the melting of the bumps so that the mounting tool does not crush the melted bumps.

### SUMMARY

Some embodiments of the present disclosure provide a mounting tool and a mounting apparatus capable of suppressing occurrence of bump crushing.

A mounting tool according to an embodiment of the present disclosure includes a holding body configured to hold an electronic component to be heated, and a support body configured to support the holding body, wherein the holding body includes a holder configured to hold the electronic component on a holding surface as a lower surface of the holder, and a placer provided above the holding surface and having a placement surface facing downward, and wherein the support body includes an accommodator configured to accommodate the placer so that the holding surface is exposed downward and the holding body is movable vertically, and a support configured to support the holding body by being in contact with the placement surface.

A mounting apparatus according to an embodiment of the present disclosure includes the mounting tool of Claim 1, and a mounting head configured to be movable toward and away from a substrate on which an electronic component is to be mounted, and having a lower end to which the mounting tool is attached

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a partial cross-sectional view showing a mounting tool according to an embodiment before an electronic component is mounted.

FIG. 2A is a side view of a mounting apparatus according to an embodiment when an image is captured by an imager, and FIG. 2B is a side view of the mounting apparatus when an electronic component is mounted.

FIG. 3 is a partial cross-sectional view of the mounting tool when bumps of an electronic component are brought into contact with bumps of a substrate.

FIG. 4 is a partial cross-sectional view of the mounting tool when a negative pressure at suction ports is released.

FIG. 5 is a partial cross-sectional view of the mounting tool when the bumps are melted by heating.

FIG. 6 is a partial cross-sectional view of the mounting tool showing when a holder is separated from the electronic component.

FIG. 7 is a timing chart showing operations of the mounting tool.

FIG. 8 is a partial cross-sectional view showing a modification in which suction ports are provided on an upper side.

FIG. 9 is a partial cross-sectional view showing the modification of FIG. 8 during suction.

FIG. 10 is a partial cross-sectional view of a mounting tool having suction ports provided on a lateral side.

FIG. 11 is a partial cross-sectional view of a modification in which a support and a placement surface have inclined portions.

FIG. 12 is a partial cross-sectional view showing a modification in which a support and a placement surface have inclined portions.

FIG. 13 is a partial cross-sectional view showing a modification in which a support and a placement surface have vertical portions.

FIG. 14 is a partial cross-sectional view showing a modification of a placer.

FIG. 15 is a partial cross-sectional view showing a modification in which a heater is provided in the mounting head.

FIG. 16 is a partial cross-sectional view showing an example of a method of manufacturing a mounting tool.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a mounting tool and a mounting apparatus according to the present disclosure will be described in detail with reference to the drawings. The drawings are schematic diagrams, and a size and proportions of individual components are exaggerated for ease of understanding.

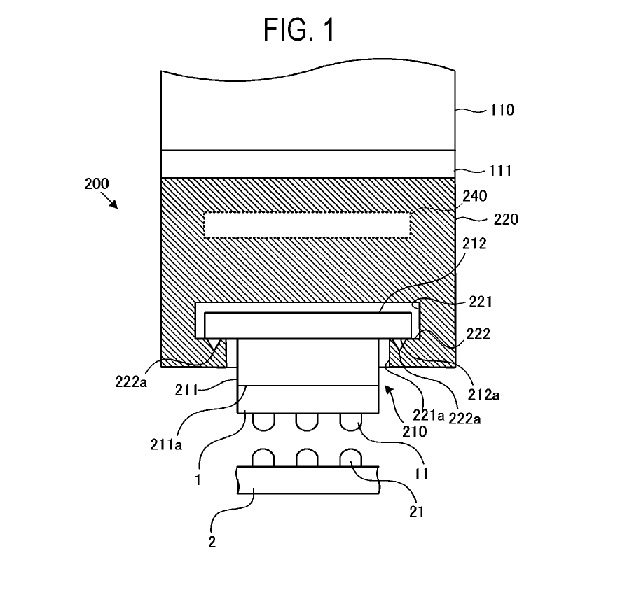

As shown in FIG. 1, an electronic component 1 mounted in the present embodiment is, for example, a semiconductor chip made of silicon. Bumps 11, which are protruding electrodes made of a solder material, are formed on the electronic component 1. The electronic component 1 is mounted on a plate-shaped substrate 2. Bumps 21, which are protruding electrodes made of a solder material, are formed on a conductive pattern of the substrate 2. The bumps 11 and 21 have a structure in which the solder material is provided in a dome shape at a top of a copper (Cu) pillar standing on an aluminum electrode pad, for example.

### Mounting Apparatus

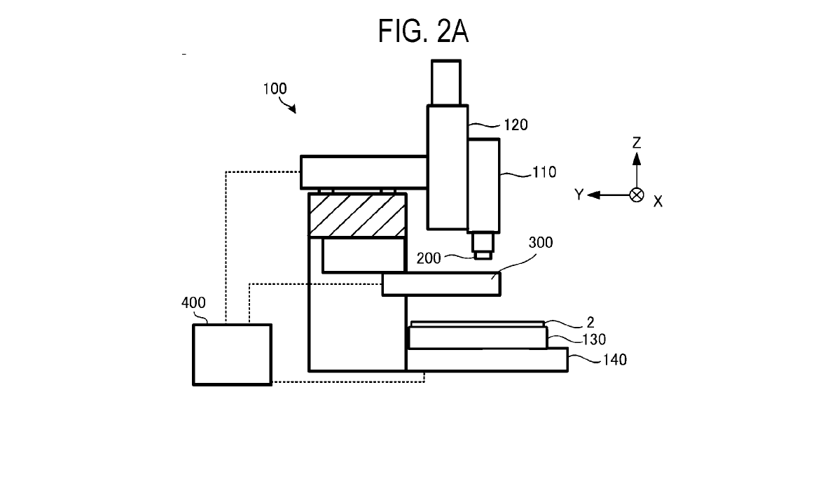

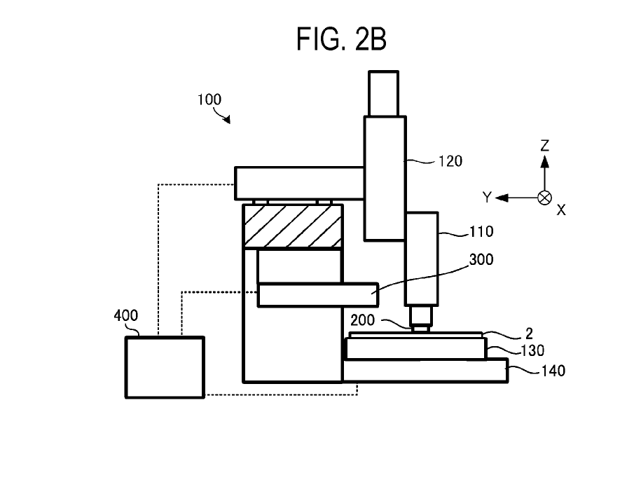

A mounting apparatus 100 is an apparatus that mounts the electronic component 1 on the substrate 2. As shown in FIGS. 2A and 2B, the mounting apparatus 100 includes a mounting head 110, a head moving mechanism 120, a substrate stage 130, a stage moving mechanism 140, an imager 300, and a control device 400. In the mounting apparatus 100, the electronic component 1 picked up by a pickup device from an electronic component supply device is delivered to a mounting tool 200 of the mounting head 110, and the mounting tool 200 is lowered by the head moving mechanism 120 to mount the delivered electronic component 1 on the substrate 2, which is placed on the substrate stage 130 and located at a mounting position by the stage moving mechanism 140. At this time, the electronic component 1 and the substrate 2 are imaged by the imager 300 and are positioned in place. Each of the parts described above is controlled by the control device 400.

The mounting head 110 is configured to move toward and away from the substrate 2 on which the electronic component 1 is to be mounted, and the mounting tool 200 that holds the electronic component 1 is attached to a lower end of the mounting head 110. Specifically, the mounting head 110 receives the electronic component 1 from the pickup device (not shown) at a delivery position, and mounts the electronic component 1 on the substrate 2 at the mounting position by descending toward the substrate 2 (see FIG. 2B).

The head moving mechanism 120 moves the mounting head 110 between the delivery position and the mounting position. At the mounting position, the head moving mechanism 120 raises and lowers the mounting head 110 to mount the electronic component 1 on the substrate 2.

The substrate stage 130 is a stage on which the substrate 2 is placed. The substrate stage 130 slides on a horizontal XY plane. The stage moving mechanism 140 causes the substrate stage 130 to slide on the XY plane.

The imager 300 is a camera that captures images of an alignment mark of the electronic component 1 and an alignment mark of the substrate 2 at the mounting position. The imager 300 is, for example, a dual-field camera with upper and lower views, and is configured to enter between the mounting head 110 and the substrate stage 130 (see FIG. 2A).

### Mounting Tool

As shown in FIG. 1, the mounting tool 200 is a tool for use in thermally welding or thermally pressing the electronic component 1 and the substrate 2. The mounting tool 200 includes a holding body 210 that holds the electronic component 1, and a support body 220 that supports the holding body 210.

### Holding Body

The holding body 210 includes a holder 211 and a placer 212. The holder 211 is a rectangular block. A lower surface of the holder 211 is a holding surface 211a that holds the electronic component 1. The holding surface 211a is rectangular and is equal to or greater than an upper surface of the electronic component 1. The holding surface 211a has suction holes (not shown), and suctions and holds the electronic component 1 by applying a negative pressure via an air passage (not shown) provided in the holder 211. A configuration for applying the negative pressure will be described later, because the support body 220 is involved.

The placer 212 is provided above the holding surface 211a of the holder 211 and has a placement surface 212a that faces downward. In the present embodiment, the placer 212 is a rectangular plate that extends horizontally outward from the holding surface 211a. The placer 212 is formed integrally with the holder 211, and a cross-section of the holding body 210 in a Z direction (vertical direction) perpendicular to the XY plane has an inverted convex shape.

In order to implement a light load to be described later, a ratio of a weight of the holding body 210 to a horizontal area of the electronic component 1 may be 0.1 g/mm² or less when the holding body 210 is separated from the support body 220. For example, the weight of the holding body 210 is 10 g to 20 g. However, the weight of the holding body 210 is not limited to the aforementioned values.

### Support Body

The support body 220 includes an accommodator 221 and a support 222. The accommodator 221 accommodates the placer 212 so that the holding surface 211a is exposed downward and the holding body 210 can move vertically.

The support body 220 of the present embodiment has a rectangular parallelepiped shape, and the accommodator 221, which is a rectangular parallelepiped-shaped cavity capable of accommodating the placer 212, is formed inside the support body 220. An opening 221a is formed at a bottom of the accommodator 221. The opening 221a is a through-hole, which is smaller than a lower surface of the support body 220 and is large enough to allow the holder 211 to pass therethrough. In a state in which the placer 212 is accommodated in the accommodator 221, the holding surface 211a of the holding body 210 protrudes downward from the opening 221a.

The support 222 is in contact with the placement surface 212a to support the holding body 210. The support 222 is an outer peripheral portion of the opening 221a in the lower surface of the support body 220, and an upper surface of the support 222 is in contact with the placement surface 212a accommodated in the accommodator 221 from below.

The holding surface 211a holds the electronic component 1 to be mounted, and after mounting, releases the holding state to separate the electronic component 1 therefrom. Specifically, the holding surface 211a has a plurality of suction holes (not shown). The suction holes are connected to a negative pressure generator including a vacuum pump, a valve, and the like via flow paths provided inside the holding body 210 and inside the support body 220. The negative pressure generator generates a negative pressure inside the suction holes, thereby suctioning the electronic component 1 at the suction holes. The electronic component 1 is held on the holding surface 211a by suctioning the electronic component 1 at the suction holes. The electronic component 1 is detached from the holding surface 211a by releasing the negative pressure. As will be described later, the electronic component 1 is supported on the substrate 2 by bringing the bumps 11 of the electronic component 1 into contact with the bumps 21 of the substrate 2. Thus, the negative pressure is released at a moment of the contact to release the electronic component 1 from the support body 220.

As described above, although the support body 220 allows the placer 212 to move vertically inside the accommodator 221, suction ports 222a that suction the holding body 210 by a negative pressure are provided in the support body 220. In the present embodiment, the suction ports 222a are openings provided at positions where the placement surface 212a is suctioned by the negative pressure. In other words, the suction ports 222a are provided at positions facing the placement surface 212a from below. The suction ports 222a are in communication with a negative pressure generator including a vacuum pump, a valve, and the like (not shown) via a flow path provided inside the support body 220. The suction ports 222a can be switched between on and off of suctioning by the valve.

Further, a heater 240 is embedded in the support body 220. As the heater 240, for example, a pulse heater that generates heat instantaneously when a voltage is applied is used. Furthermore, the support body 220 is attached to the lower end of the mounting head 110 via a heat insulator 111. The heater 240 heats the electronic component 1 and the bumps 11 and 21 from the support body 220 via the holding body 210.

As will be described later, even when the placement surface 212a is separated from the support 222, since the holding body 210 is heated by contact between an inner surface of the support body 220 and an outer surface of the holding body 210, or by radiant heat via a very narrow gap therebetween, the bumps 11 and 21 can be heated.

### Control Device

The control device 400 controls a startup, a stop, a speed, and operation timings of the mounting apparatus 100. The control device 400 can be implemented by, for example, a dedicated electronic circuit or a computer operated by a specified program. The control device 400 is connected to an input device via which an operator inputs instructions and information necessary for control and an output device via which the operator can check a status of the apparatus.

When the holding surface 211a suctions and holds the electronic component 1 by a negative pressure, the control device 400 of the present embodiment fixes the holding body 210 to the support body 220 by suctioning the placer 212 by the negative pressure acting on the suction ports 222a. Further, when a detector as a laser sensor (not shown) detects that the mounting tool 200 is lowered to a height position where the bumps 11 of the electronic component 1 are brought into contact with the bumps 21 of the substrate 2, the control device 400 performs heating by the heater 240 and releases the negative pressure acting on the suction ports 222a.

### Operations

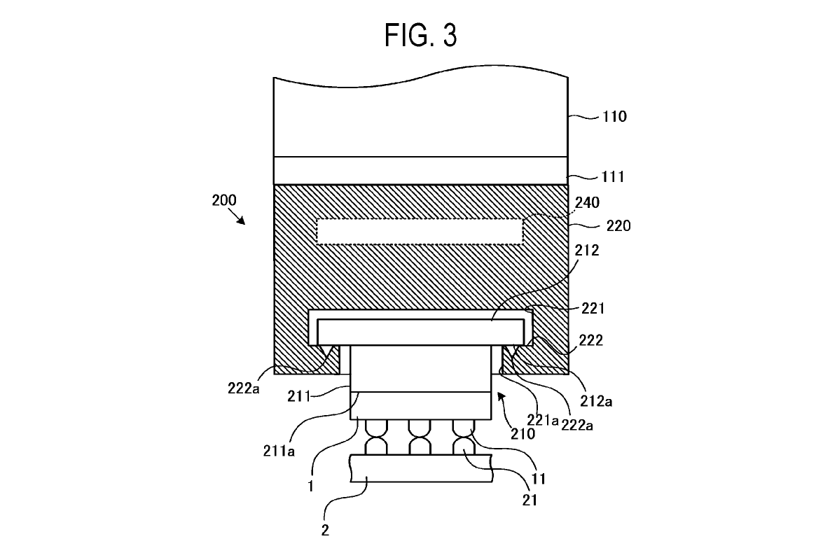

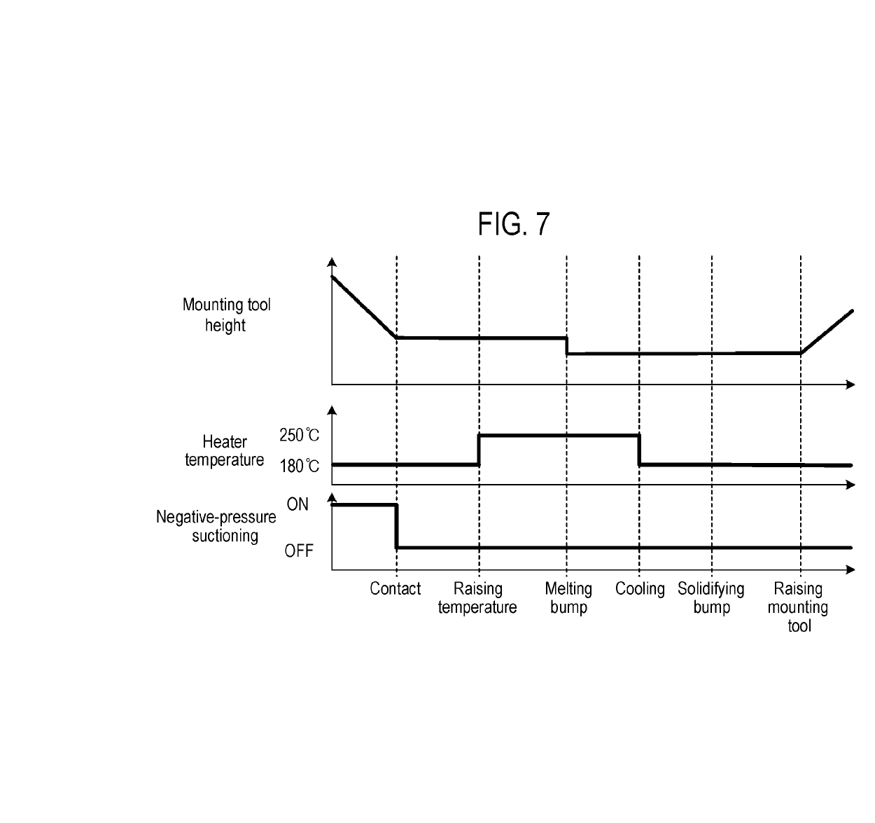

Operations of the mounting apparatus 100 according to the present embodiment described above will be explained with reference to FIGS. 3 to 7 in addition to FIGS. 1 to 2B. FIG. 7 is a timing chart showing changes in a height of the mounting tool 200, a temperature of the heater 240, and on and off of the negative-pressure suctioning via the suction ports 222a.

First, the heater 240 preheats the holding body 210 to about 180 degrees C. Further, as shown in FIG. 1, the holding body 210 is fixed to the support body 220 by suctioning the placer 212 by the negative pressure acting on the suction ports 222a. In this state, as shown in FIG. 1, the holding surface 211a receives the electronic component 1 transferred by the pickup device, by suctioning and holding the electronic component 1 by the negative pressure. Thus, the electronic component 1 is held by the mounting head 110 with the bumps 11 facing downward.

The head moving mechanism 120 moves the mounting head 110 to the mounting position, and the stage moving mechanism 140 moves the substrate stage 130 to the mounting position. At this time, the stage moving mechanism 140 moves the substrate stage 130 so that a region in the substrate 2 where the electronic component 1 is to be mounted (hereinafter referred to as a planned mounting region) is located at the mounting position. Thereafter, as shown in FIG. 2A, a dual-field camera (imager 300) with upper and lower views is advanced to a space between the mounting head 110 and the substrate 2, and captures images of the alignment mark of the electronic component 1 located above the camera and the alignment mark of the planned mounting region of the substrate 2 located below the camera, thereby performing position alignment between the electronic component 1 and the planned mounting region of the substrate 2.

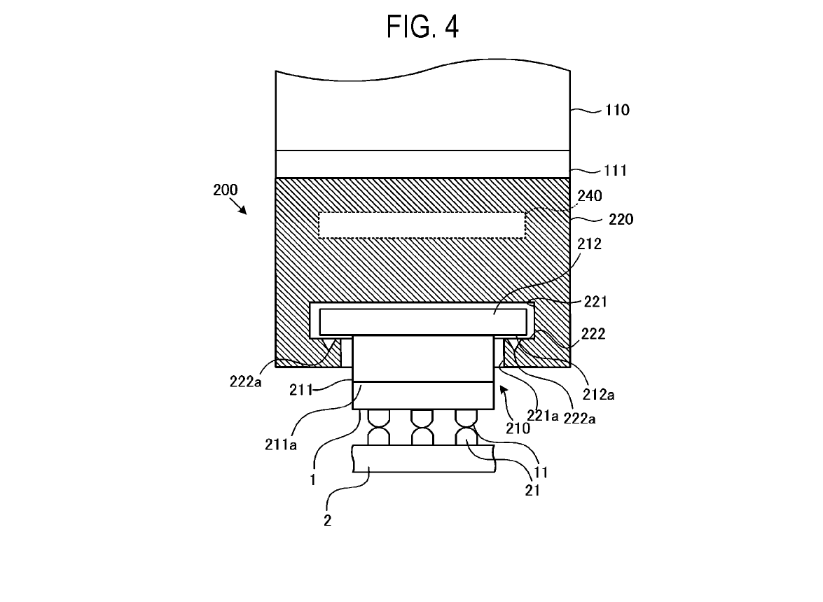

After the alignment, as shown in FIG. 3, the head moving mechanism 120 lowers the mounting head 110 to a position where the bumps 11 on the electronic component 1 are brought into contact with the bumps 21 on the substrate 2 (see "Mounting tool height" in FIG. 7). At the same time as the contact occurs, the negative pressure acting on the suction ports 222a is released (see "Negative-pressure suction OFF" in FIG. 7). With this operation, as shown in FIG. 4, the placer 212 moves slightly away from the support 222 of the support body 220, resulting in a light load state in which only a weight of the holding body 210 is applied to the bumps 11 and 21.

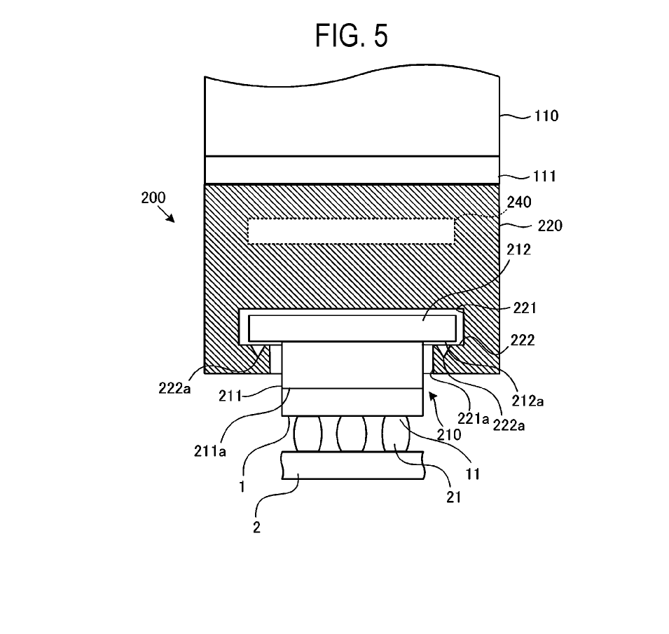

Subsequently, the heater 240 raises a temperature to about 250 degrees C (see "Heater temperature" in FIG. 7). Because the heater 240 raises the temperature to about 250 degrees C, the bumps 11 and 21 are melted as shown in FIG. 5. Thereafter, by lowering the temperature of the heater 240 to the preheating temperature of 180 degrees C (see "Heater temperature" in FIG. 7), the bumps 11 and 21 are cooled and solidified. At this time, since the electronic component 1 and the bumps 11 and 21 are in the light load state in which only the weight of the holding body 210 is applied thereto, crushing of the bumps 11 and 21 hardly occurs.

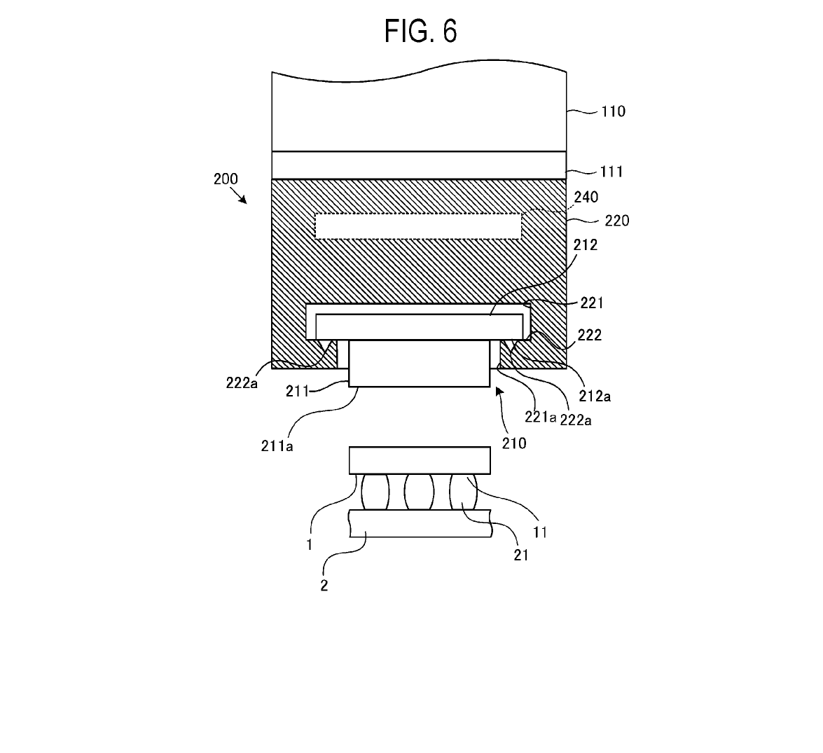

Thereafter, as shown in FIG. 6, the negative pressure acting on the holding surface 211a is released, and the mounting tool 200 is raised (see "Mounting tool height" in FIG. 7) after the bumps 11 and 21 are cooled and solidified. Thus, the electronic component 1 is mounted on the substrate 2.

### Effects

(1) The mounting tool 200 of the present embodiment includes the holding body 210 configured to hold the electronic component 1 to be heated, and the support body 220 configured to support the holding body 210. The holding body 210 includes the holder 211 configured to hold the electronic component 1 on the holding surface 211a as the lower surface thereof, and the placer 212 provided above the holding surface 211a and having the placement surface 212a facing downward. The support body 220 includes the accommodator 221 configured to accommodate the placer 212 so that the holding surface 211a is exposed downward and the holding body 210 can move vertically, and a support 222 configured to support the holding body 210 by being brought into contact with the placement surface 212a.

With this configuration, since the holding body 210 is movable relative to the support body 220 when the bumps 11 and 21 are melted by heating, even when the bumps 11 and 21 are brought into contact with each other, the holding body 210 is separated from the mounting head 110, and the load by the weight of the holding body 210 only, which is a very light load, is applied to the electronic component 1. Thus, it is possible to suppress the bumps 11 and 21 from being crushed. As described above, the load applied by only the single holding body 210 that holds the electronic component 1 is significantly smaller than a load of the mounting head 110, and is a light load that cannot be achieved even by a cylinder or a voice coil motor.

Since the holding body 210 is separated from the support body 220, the holding body 210 is not affected by thermal expansion of the support body 220. In addition, the holding body 210 can move upward. Thus, displacement of the holding body 210 due to thermal expansion of itself is directed upward rather than downward, where the bumps 11 and 21 are in contact with each other. Therefore, displacement of the electronic component 1 directing downward due to thermal expansion is minimized, and it is possible to prevent the bumps 11 and 21 from being crushed by compression caused by the thermal expansion. Further, it is not necessary to perform a complex control, such as detecting the moment of the melting of the bumps 11 and 21 to raise the mounting tool 200.

(2) The placer 212 extends further outward than the holding surface 211a. Therefore, since the support 222 supports the placer 212 at a position outward from the holding surface 211a, the holding body 210 is supported stably. Further, even when the holding body 210 moves downward due to its own weight when the bumps 11 and 21 are melted, the support 222 supports the placer 212. Therefore, the holding body 210 does not move downward than a position where the support 222 supports the placer 212. In other words, the support 222 serves as a stopper for the holding body 210. With this configuration, it is possible to prevent the melted bumps from being crushed without a complex control of operations of the mounting head.

(3) The support body 220 allows the placer 212 to move vertically inside the accommodator 221, and has the suction ports 222a configured to suction the holding body 210 by a negative pressure. In the present embodiment, the suction ports 222a are provided at positions where the placement surface 212a is suctioned by the negative pressure. Therefore, after the position of the electronic component 1 is recognized and the electronic component 1 is positioned relative to the substrate 2 and before the bumps 11 and 21 are brought into contact with each other, the holding body 210 can be fixed by applying the negative pressure to the suction ports 222a. By applying the negative pressure to the suction ports 222a to fix the holding body 210, the position of the electronic component 1 can be stabilized, and the bumps 11 and 21 facing each other can be aligned accurately. Further, release of the fixing of the holding body 210 to the support body 220 can be controlled easily by releasing the negative pressure. Furthermore, by applying the negative pressure to the suction ports 222a to fix the holding body 210 when the mounting head 110 moves vertically, it is possible to prevent the holding body 210 from flapping (moving or shaking wildly) inside the accommodator 221. Accordingly, it is possible to prevent the holding body 210 from coming into contact with the accommodator 221 and generating particles.

(4) The support body 220 includes the heater 240. Since heat from the support body 220 is transferred to the holding body 210 by contact with the support body 220 or by radiant heat, the electronic component 1 can be heated quickly by the holding body 210. Further, since the heater 240 is not provided in the holding body 210, the electronic component 1 can be heated without increasing the weight of the holding body 210.

### Modifications

The present embodiment is not limited to the above description. For example, the following modifications may also be adopted.

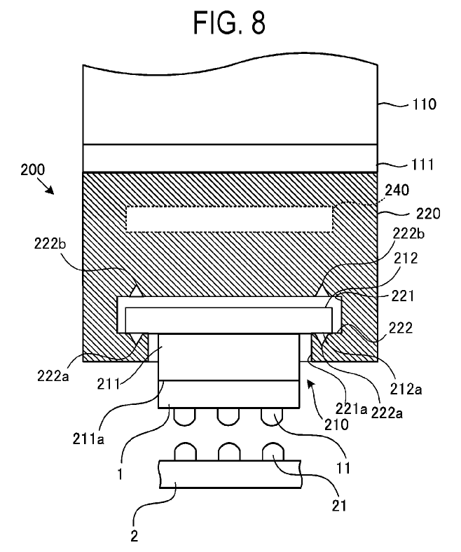

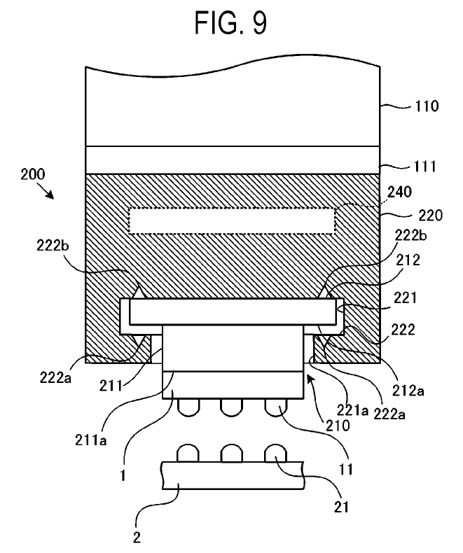

(1) By pressing the electronic component 1 and the substrate 2 in a state in which the holding body 210 is in contact with a ceiling of the accommodator 221, pressurization with a high load can be achieved. As shown in FIG. 8, in addition to the suction port 222a, suction ports 222b may be provided at a position where an upper surface of the holding body 210 (an upper surface of the placer 212) is suctioned by a negative pressure. The suction ports 222b may be provided on the ceiling of the accommodator 221 that faces the placer 212 from above. In this case, on and off of the suctioning by the negative pressure generated by the negative pressure generator can be switched between the suction port 222a and the suction ports 222b by a valve. As a result, as shown in FIG. 9, by applying the negative pressure to the suction ports 222b to suction the upper surface of the holding body 210 (the upper surface of the placer 212), the weight of the mounting head 110 as it is can be applied to the electronic component 1, and thus it is possible to perform pressurization with a heavy load. With this configuration, a light load and a heavy load can be switched according the electronic component 1 to be mounted. The number of suction ports 222b is not limited to that shown in FIG. 8. The number of suction ports 222b may be one, or three or more.

Further, the suction ports 222a may be provided along an inner side of an outer periphery of the placement surface 212a. When it is difficult to provide the suction ports 222a along the inner side of the outer periphery of the placement surface 212a, a pair of suction ports 222a may be provided at opposing left-hand side and right-hand side positions.

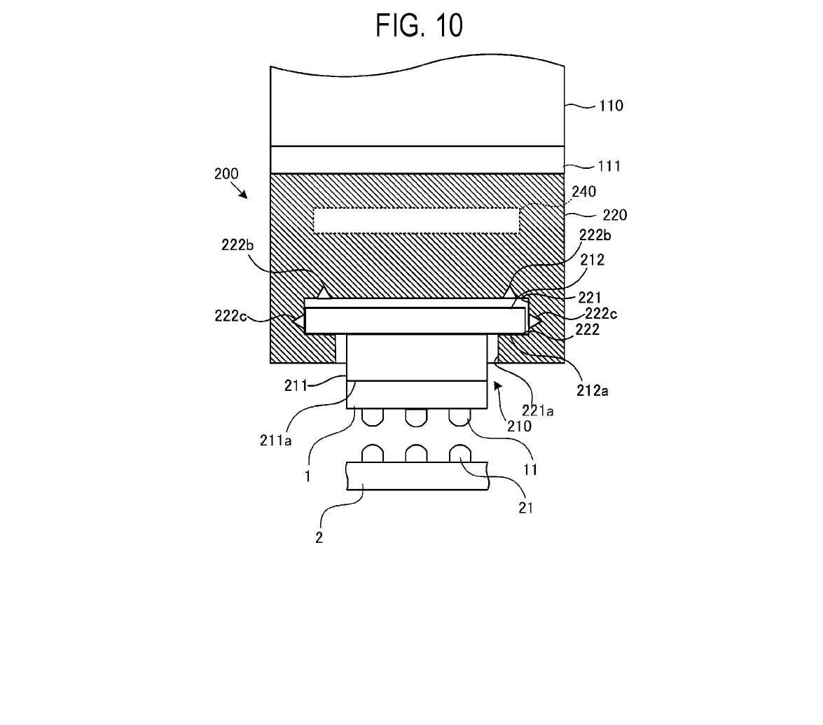

(2) As shown in FIG. 10, suction ports 222c may be provided at positions where side surfaces of the holding body 210 (side surfaces of the placer 212) are suctioned by a negative pressure. That is, the suction ports 222c to which a negative pressure generated from a negative pressure generator is applied are provided in the inner surface of the support body 220 at positions facing the outer surface of the holding body 210. FIG. 10 shows an example in which the suction ports 222c are provided in two opposing inner surfaces of the support body 220 that face two opposing side surfaces of the holding body 210 (two opposing side surfaces of the placer 212), respectively. In this case, by applying the negative pressure to one of the suction ports 222c, the side surface of the holding body 210 (the side surfaces of the placer 212) is suctioned and held by the inner surface in which the one suction port 222c is provided. However, the suction ports 222c may be provided at positions corresponding to one of the side surfaces of the holding body 210 (one of the side surfaces of the placer 212), or at positions corresponding to any two adjacent side surfaces of the holding body 210 (any two adjacent side surfaces of the placer 212), to suction and hold the holding body 210. Specifically, by suctioning the two adjacent side surfaces of the holding body 210 (the two adjacent side surfaces of the placer 212), the holder 211 can be positioned in place.

As shown in FIG. 10, the suction ports 222b may also be provided at positions where the upper surface of the holding body 210 (the upper surface of the placer 212) is suctioned by the negative pressure. In FIG. 10, the suction ports 222b are provided at positions where the upper surface of the holding body 210 (the upper surface of the placer 212) is suctioned, and the suction ports 222c re provided at positions where the side surfaces of the holding body 210 (the side surfaces of the placer 212) are suctioned. However, either the suction ports 222b or the suction ports 222b may be provided. In any of the configurations described above, when the mounting tool 200 moves, the placer 212 of the holding body 210 may be fixed inside the accommodator 221 by suctioning by any of the suction ports 222a, 222b, and 222c.

(3) The negative pressure at the suction ports 222a or the suction ports 222c may be released either when the bumps 11 and 21 are brought into contact with each other or after the bumps 11 and 21 are melted. Further, it is not necessary to release the negative pressure at the suction ports 222a or the suction ports 222c completely. In other words, even when the suctioning by the negative pressure continues, as long as the suctioning is relatively weak, the load applied to the bumps 11 and 21 can be reduced to suppress the bumps 11 and 21 from being crushed, as described above. In other words, a magnitude of the negative pressure may be adjusted. Further, when a combined force of a suction force of the negative pressure and the weight of the holding body 210 is 0.1 g/mm² or less with respect to the horizontal area of the electronic component 1, it is not necessary to perform the release of the negative pressure and the adjustment of the magnitude of the negative pressure. Furthermore, the suction ports 222a, the suction ports 222b, and the suction ports 222c may be circular holes, elongated holes, or slits, as long as they can hold the holding body 210.

When the load of the mounting tool 200 is too light, non-contacting bumps 11 and 21 may be generated due to variations in height of the bumps 11 and 21. For this reason, it is necessary to apply a load that does not generate such non-contacting bumps 11 and 21, and the load can be adjusted not only by the weight of the mounting tool 200 itself but also by adding suctioning by a negative pressure.

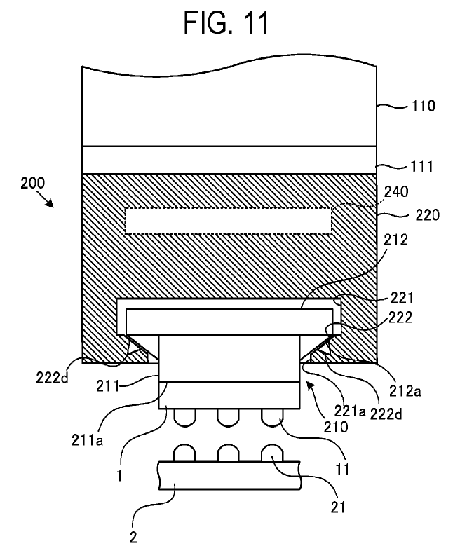

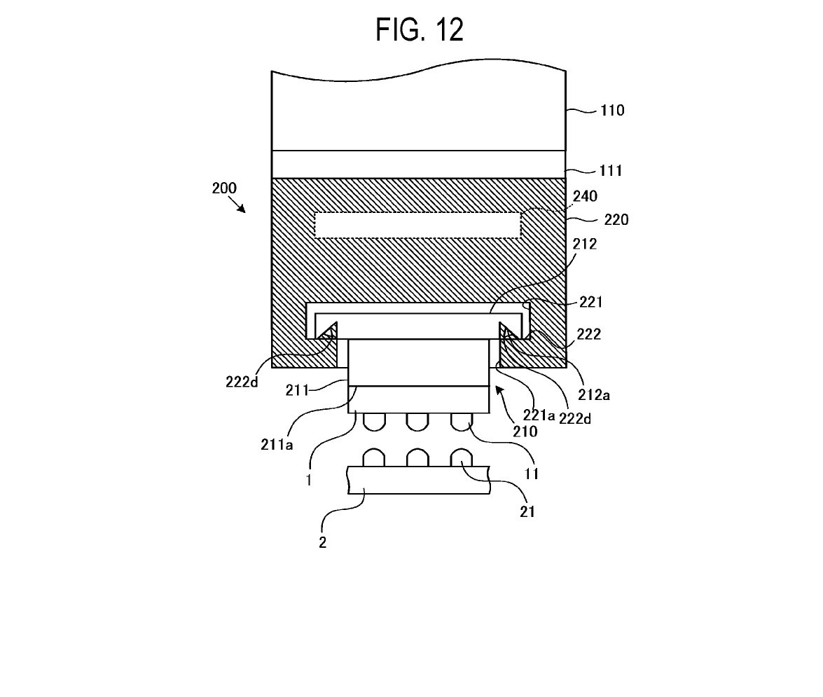

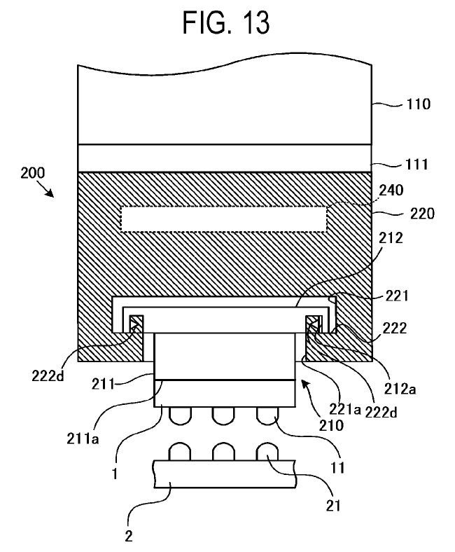

(4) As shown in FIGS. 11 and 12, a part or an entirety of the upper surface of the support 222 and a part or an entirety of the placement surface 212a may be surfaces inclined at angles other than horizontal. For example, the upper surface of the support 222 and the placement surface 212a may have portions inclined with respect to horizontal as shown in FIGS. 11 and 12, or may have portions extending in the vertical direction as shown in FIG. 13. Suction ports 222d may be provided according to the angles of the support 222 and the placement surface 212a. The inclined surfaces of the support 222 and the placement surface 212a may have any angle as long as they do not hinder the placer 212 from moving vertically inside the accommodator 221. Further, the inclination angles of the inclined or vertical surfaces of the support 222 and the placement surface 212a, which face each other and are in contact with each other, may be a same angle. However, the inclination angles are not limited to the same angle. The inclination angles may be different from each other as long as the suction ports 222d can suction the placement surface 212a.

In the configuration of FIG. 13, the suction ports 222d may be provided at positions corresponding to the placement surface 212a of the holding body 210. FIG. 13 shows an example in which the suction ports 222d are provided in two opposing inner surfaces of the support body 220 that face opposing placement surfaces 212a of the holding body 210. However, the suction ports 222d may be provided at positions corresponding to any one of the placement surfaces 212a of the holding body 210, or at positions corresponding to any two adjacent placement surfaces 212a, to suction and hold the placement surfaces 212a. Specifically, by suctioning the two adjacent placement surfaces 212a, the holder 211 can be positioned in place.

With the configurations illustrated in FIGS. 11 and 12, the holding body 210 is centered and prevented from being misaligned.

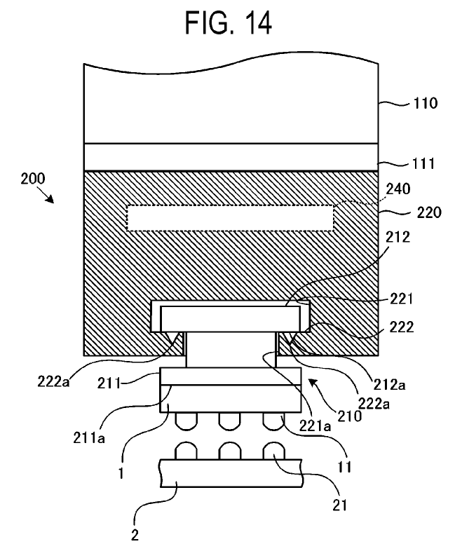

(5) The placer 212 needs not extend further outward than the holding surface 211a. For example, as shown in FIG. 14, a length of the placer 212 in a horizontal direction may be equal to or smaller than that of the holding surface 211a.

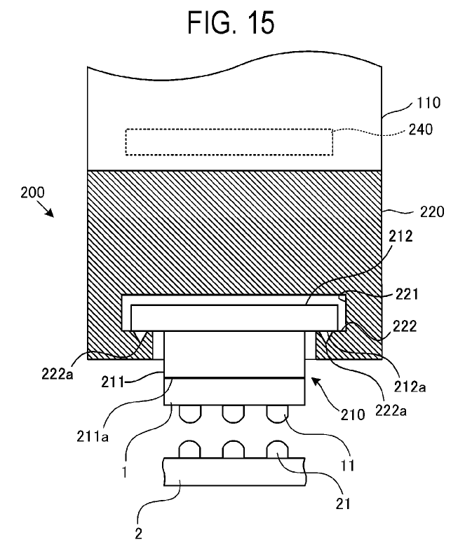

(6) The heater 240 may be provided separately from the support body 220. For example, as shown in FIG. 15, the heater 240 may be provided in the mounting head 110, and the electronic component 1 and the bumps 11 and 21 may be heated via the support body 220 and the holding body 210. With this configuration, it is not necessary to provide a heating wiring or the like for the mounting tool 200, and it becomes easy to replace the mounting tool 200 according to the electronic component 1.

(7) The holding body 210 may be configured so that the holder 211 and the placer 212 are detachably attached. With this configuration, the holding surface 211a can be replaced according to the electronic component 1.

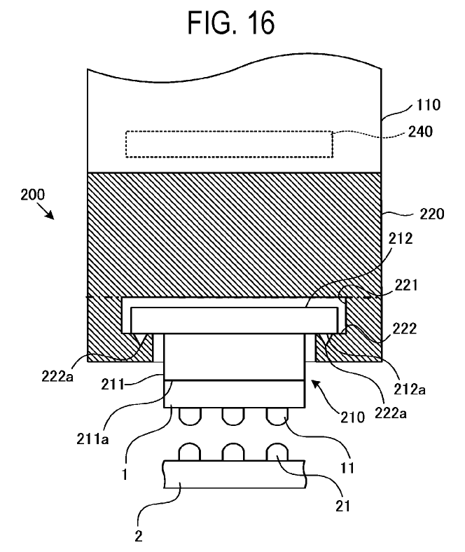

(8) Various methods of manufacturing the mounting tool 200 including the holding body 210 and the support body 220 are conceivable. For example, as shown in FIG. 16, the support body 220 may be manufactured by combining separately formed components. That is, the support body 220 is formed by inserting the holding body 210 into the accommodator 221 and then attaching the support 222, which is formed separately from the main body of the support body 220, to a portion indicated by the one-dot chain line. With this configuration, insertion and replacement of the holding body 210 with respect to the accommodator 221 can be facilitated. More specifically, when the support body 220 is configured to be separable into an upper member and a lower member including the support 222 based on the one-dot chain line portion as a boundary, the holding body 210 may be disposed as the lower member and then fixed at the one-dot chain line portion by bonding or by a fastener such as screws or the like.

In the configuration illustrated in FIG. 16, the heater 240 is provided in the mounting head 110. Alternatively, the heater 240 may be provided in the support body 220. That is, the heater 240 may be provided in either or both of the mounting head 110 and the support body 220. Although the heat insulator 111 is not shown in FIG. 16, the heat insulator 111 may be provided on a boundary with a portion that is located (on a side of the mounting head 110) above the heater 240 disposed in either or both of the mounting head 110 and the support body 220 and requires insulation.

(9) The support body 220 may have discharge ports for discharging a gas to the holding body 210. By discharging the gas from the discharge ports, the holding body 210 can be pressed and fixed against an inner surface (the inner side surface, the ceiling, or the support 222) of the accommodator 221. With this configuration, the same fixing effect as described above can be achieved. For example, the suction ports 222a illustrated in FIG. 1 above serve as the discharge ports. The discharge ports are in communication with a positive pressure generator including a vacuum pump, a valve, and the like via a flow path provided inside the support body 220. By discharging the gas from the discharge ports by the positive pressure generator, the holding body 210 can be pressed against the ceiling of the accommodator 221. By discharging the gas from discharge ports provided in the ceiling of the accommodator 221, the holding body 210 can also be pressed against the support 222. By discharging the gas from discharge ports provided in one inner surface of the accommodator 221, the holding body 210 can also be pressed against another inner side surface of the accommodator 221. Specifically, by discharging the gas from discharge ports provided in two adjacent inner surfaces of the accommodator 221, the holding body 210 can be pressed against a corner of the two opposing inner surfaces and the holder 211 can be positioned in place.

Further, as in the configuration illustrated in FIG. 8, in addition to the suction ports 222a as the discharge ports, the suction ports 222b may be provided to suction the holding body 210, thereby fixing the holding body 210 to the ceiling of accommodator 221. In other words, the holding body 210 can be fixed by using pairs of a discharge port and a suction port opposing to each other, wherein the discharge port performs gas discharge and the suction port performs gas suctioning.

Similarly, as in the configurations illustrated in FIGS. 10 and 13, the holding body 210 may be fixed by discharging a gas from, among the suction ports 222c (in the case of FIG. 10) or the suction ports 222d (in the case of FIG. 13) provided at positions where the side surfaces of the holding body 210 are suctioned, one of the suction ports 222c (as a discharge port) corresponding to two side surfaces facing each other or one of the suction ports 222d (as a discharge port) corresponding to two side surfaces facing each other, and suctioning the gas from the other one of the suction ports 222c or the other one of the suction ports 222d. In addition, specifically, by discharging a gas from, among the suctions ports 222c (in the case of FIG. 10) or the suction ports 222d (in the case of FIG. 13) corresponding to four side surfaces, the suction ports 222c (as discharge ports) corresponding to two adjacent side surfaces or the suction ports 222d (serving as discharge ports) that correspond to two adjacent side surfaces, and suctioning the gas from the suction ports 222c or the suction ports 222d corresponding to two adjacent side surfaces facing the above-mentioned two side surfaces, the holder 211 can be positioned in place.

In addition, in the configurations illustrated in FIGS. 8, 10, 11, 12 and 13, the holding body 210 may be fixed by using all of the suction ports 222a, 222b, 222c, and 222d in the respective configurations as discharge ports, and discharging a gas from all of the suction ports 222a, 222b, 222c, and 222d in the respective configurations.

According to the present disclosure in some embodiments, it is possible to provide a mounting tool and a mounting apparatus capable of suppressing occurrence of bump crushing.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A mounting tool comprising:
a holding body configured to hold an electronic component to be heated; and
a support body configured to support the holding body,
wherein the holding body includes:
a holder configured to hold the electronic component on a holding surface as a lower surface of the holder; and
a placer provided above the holding surface and having a placement surface facing downward, and
wherein the support body includes:
an accommodator configured to accommodate the placer so that the holding surface is exposed downward and the holding body is movable vertically; and
a support configured to support the holding body by being in contact with the placement surface.

2. The mounting tool of claim 1, wherein the placer extends further outward than the holding surface.

3. The mounting tool of claim 1, wherein the support body allows the placer to move vertically inside the accommodator, and has a suction port configured to suction the holding body by a negative pressure.

4. The mounting tool of claim 3, wherein the suction port is provided at a position where the placement surface is suctioned by the negative pressure.

5. The mounting tool of claim 3, wherein the suction port is provided at a position where a side surface of the holding body is suctioned by the negative pressure.

6. The mounting tool of claim 3, wherein the suction port is provided at a position where an upper surface of the holding body is suctioned by the negative pressure.

7. The mounting tool of claim 1, wherein the support body includes a heater.

8. The mounting tool of claim 1, wherein a part or an entirety of an upper surface of the support and a part or an entire of the placement surface are surfaces inclined at angles other than horizontal.

9. The mounting tool of claim 1, wherein the support body allows the placer to move vertically inside the accommodator, and has a discharge port configured to discharge a gas toward the holding body.

10. The mounting tool of claim 1, wherein an opening allowing the holder to be inserted into and pass through the opening is provided at a bottom of the accommodator, and
wherein the support is an outer peripheral portion of the opening.

11. A mounting apparatus comprising:
the mounting tool of claim 1; and
a mounting head configured to be movable toward and away from a substrate on which an electronic component is to be mounted, and having a lower end to which the mounting tool is attached.

12. The mounting apparatus of claim 11, wherein the mounting head includes a heater.
